(19) United States
(12) Patent Application Publication
(10) Pub. No.: US 2014/0104892 A1
(43) Pub. Date: Apr. 17, 2014

(54) FM/PWM HIGH SPEED CONTROLLER FOR RESONANT TYPE SWITCHING MODE POWER SUPPLY

(71) Applicant: VICTOR ELECTRONICS LTD., Fo Tan (HK)

(72) Inventor: Yiu Kei Lau, Fo Tan (HK)

(73) Assignee: VICTOR ELECTRONICS LTD., Fo Tan (HK)

(21) Appl. No.: 13/651,422

(22) Filed: Oct. 14, 2012

(51) Int. Cl. H03K 7/08; H02M 7/21

(52) U.S. Cl. CPC H03K 7/08; H02M 7/21
USPC 363/21.01; 332/106

(57) ABSTRACT

This invention provides a high speed controller and switching mode power supply. The high speed controller includes PWM control chip, providing high speed PWM function; output circuit: sending out PWM working signal or frequency modulation working signal. FM enhancement network: inducing feedback signals from CFB and VFB circuitry to vary the oscillation frequency of the PWM control chip, and boost up the frequency modulation function. The FM enhancement network is an unique circuitry to alter the operation characteristics of the PWM control chip. In this respect the high speed controller can be regarded as a new PWM/FM controller which can work simultaneously both in PWM mode and in FM mode in accordance to the load conditions of DC/DC converter output. The efficiency of medium to high power supply using the new design as controller IC would increase at least 5% to 8% higher than other power supplies.

### FIELD OF THE INVENTION

This invention is related to electronic technology field, precisely, it is a newly designed FM/PWM high speed controller and a LC resonant switching mode power supply of medium to high power, which relies on the above preferred embodiment as the kernel controller.

### BACKGROUND OF THE INVENTION

In electronic technology, people often use switching mode power supply for stable voltage output. Many switching mode power supply would use Pulse Width Modulation technology (Pulse Width Modulation, PWM) to obtain a stable voltage.

In the market today, PWM control IC's of different types were produced to meet the demands of designers from world-wide. With the advent of cost effective MOSFETs to replace the bipolar devices, the switching frequencies of power supplies reaching a few hundred kilohertz are common in these days. However, the power loss of many magnetic ferrite materials would decrease as the switching frequency shift from a few hundred kilohertz to a hundred kilohertz or below. To meet the criteria of these magnetic ferrite materials, a switching mode power supply of medium to high output power when operating in full load condition, its switching frequency will automatically shift from a few hundred kilohertz to about a hundred kilohertz would be quite appreciative, because the efficiency would be much higher.

To achieve this goal, a new type of switching mode control IC which can work simultaneously both in PWM mode control and FM mode control is under designed, and this is the preferred embodiment of the invention.

### SUMMARY OF THE INVENTION

A high speed controller and switching mode power supply, substantially as shown in and/or described in connection with at least on of the figures, as set forth more completely in the claims, aiming at the technical problems of the prior switching mode power supply cannot drive heavy load efficiently.

According to an aspect, a high speed controller is provided, which including:
PWM control chip: providing high speed controller PWM function;
output circuit: sending out PWM working signal and frequency modulation working signal;
FM enhancement network: effectively vary the oscillation frequency and pulse width of the PWM control chip according to the feedback for different load conditions;
output circuit, FM enhancement network and IC are all assembled in a PCB, and encapsulated in a metal case, with a 8-pin connector, and fully potted with epoxy.
Advantageously, the PWM control chip is PWM control IC UC2825.
Advantageously, the FM enhancement network includes RT subcircuit, voltage feedback subcircuit and current feedback subcircuit; RT subcircuit connects to Pin 5 of the UC2825; current feedback subcircuit connects to Pin 5 of the UC2825; voltage feedback subcircuit connects to Pin 1 of the UC2825.
Advantageously, output circuit includes two output subcircuits, one connects to Pin 11 of the UC2825, and the other connects to Pin 14 of the UC2825.

According to an aspect, a switching mode power supply is provided, which including:
a high speed controller;
a driver connected to the output circuit of the high speed controller;
a switch connected to the driver;
a transformer with leakage inductance (L) and a capacitor (C) connected to the switch;
a rectifier connected to the secondary winding of transformer; current feedback circuit, connected to the transformer and the high speed controller;
voltage feedback circuit, connected to the rectifier and the high speed controller.
Advantageously, the switch (300) includes two switching modules.
Advantageously, the leakage inductance (L) of the transformer and capacitor (C) together build up the resonant circuit.
   1. This design includes two related construction units, one is the preferred embodiment of the invention and the other part is a switching mode power supply with LC resonant circuitry and rely on the said invention as kernel controller.

### 2. The Design of the Embodiment of the New Invention

The invention is a new type of PWM and FM controller network optimized for use in a serial LC resonant type circuit of switching mode power supply. It is based on PWM IC but implemented with an enhancement network which is basically equivalent to a voltage controlled nonlinear resistor. This enhancement network when in action would serve to vary the oscillation frequency of the PWM IC, thus achieved a FM mode function, together with the PWM mode function which is still in operation.
The unique feature of this new type of controller is that when it is functioning in FM mode, the output current waveform tends to be sinusoidal with zero-current switching function, that would guarantee the power supply to achieve high efficiency in heavy load conditions. At the same time, it retains the full merits of a PWM controller in light load, keeping the output voltage stable.
This new invention functions simultaneously both in the FM mode and in the PWM mode, and offers a smooth transition between the two modes.

### 3. The LC Resonant Circuit Relying on the Preferred Embodiment as Kernel Controller

Another advantage of the new invention is that the DC/DC converter using it as the kernel controller would require just a simple serial LC resonant circuit (when compared to LLC circuit). The design and fabrication of output transformer for the related DC/DC network is simple, and in practice a batch of switching mode power supply of this resonant type with output power up to 700 W has been fabricated and tested with satisfactory results.

### BRIEF DESCRIPTION OF THE DRAWINGS

This is only a brief description with reference to the drawings below, and detailed descriptions will be dealt with in the section that follows.

FIG. 1 is a block diagram illustrating the high speed controller new design; FIG. 2 is a detail circuit diagram of the new designed high speed controller in accordance with the preferred embodiment of the invention;

FIG. 3 is a block diagram illustrating the LC resonant switching mode power supply in accordance with the preferred embodiment of the invention;

FIG. 4 is a resonant curve of the switching mode power supply in accordance with the preferred embodiment of the invention;

FIG. 5 is PWM pulse control waveform at 5% load in accordance with the preferred embodiment of the invention;

FIG. 6 is PWM pulse control waveform at 10% load in accordance with the preferred embodiment of the invention;

FIG. 7 is PWM pulse control waveform at 20% load in accordance with the preferred embodiment of the invention;

FIG. 8 is PWM/FM control waveform at 50% load in accordance with the preferred embodiment of the invention;

FIG. 9 is FM pulse control waveform at 100% load in accordance with the preferred embodiment of the invention;

FIG. 10 is the output waveform of the new design and current waveform through capacitance C in FIG. 3 when power supply is at 100% load.

FIG. 11 PCB layout of the preferred embodiment. (component side) FIG. 12 PCB layout of the preferred embodiment. (bottom side) FIG. 13 Dimensions of metal case for encapsulation of the preferred embodiment.

### DETAILED DESCRIPTION OF THE PREFERRED EMBODIMENT

So as to further explain the new design, an exemplary embodiment of the present invention will be described with reference to the below drawings.

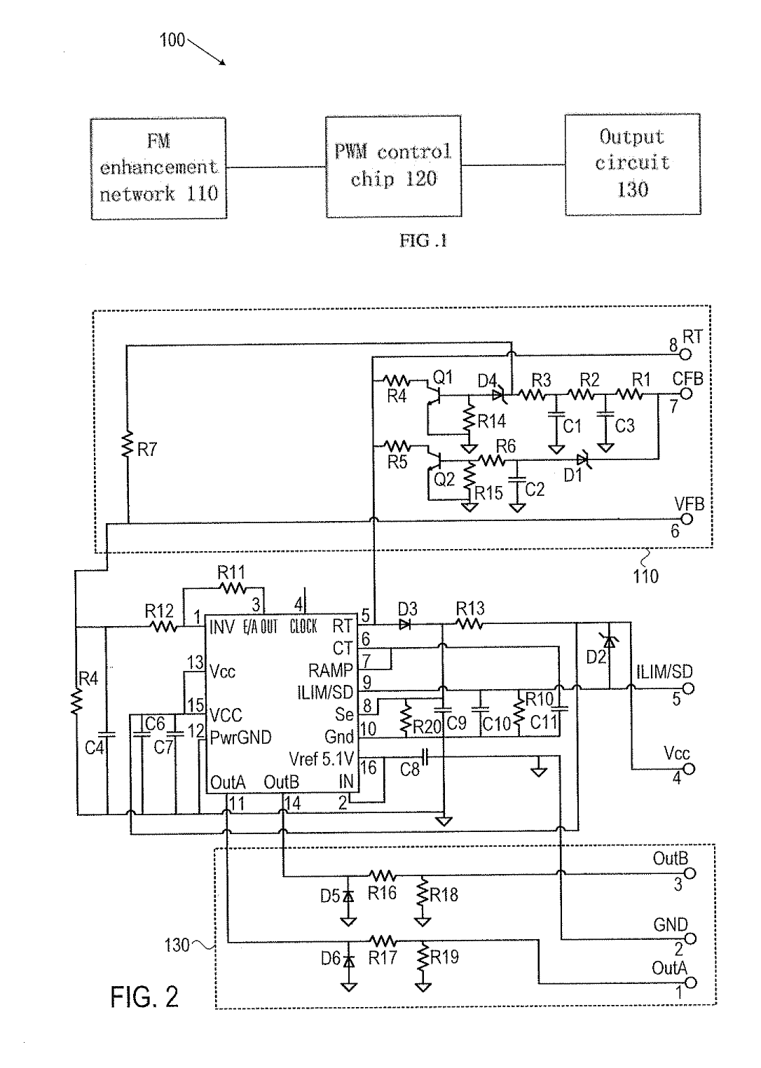

FIG. 1 is a block diagram illustrating high speed controller 100 in accordance with a preferred embodiment of the invention. Referring to FIG. 1, the high speed controller 100 includes: FM enhancement network 110, PWM control chip 120 and output circuit 130. The FM enhancement network 110, PWM control chip 120 and output circuit 130 are connected in sequence. Two different driving signals, PWM mode and FM mode (Frequency Modulation). The PWM control chip 120 can output PWM signal. On the other side, the FM enhancement network 110, which is connected to the PWM control chip 120, can output signal that change the oscillation frequency. When the PWM control chip 120 receives the signal from the FM enhancement network 110, it will change the parameters of the PWM signal which will be send to the output circuit 130. So the high speed controller 100 can work in FM mode.

FIG. 2 is a circuit diagram illustrating the high speed controller 100 in accordance with the preferred embodiment of the invention. Referring to FIG. 2, the PWM control chip 120 is a PWM control IC UC2825. The FM enhancement network 110, which is connected to Pin 1 and Pin 5 of the UC2825, would send signal which may vary the working frequency of the UC2825. The output circuit 130 connects to Pin 11 and Pin 14 of the UC2825 serves to deliver control signal to DC/DC driver.

The FM enhancement network 110 is comprised of three subcircuits. They are RT subcircuit, voltage feedback subcircuit and current feedback subcircuit. The voltage feedback subcircuit sends voltage signal to Pin 1 of the UC2825 through a resistance (R12). The RT subcircuit connects to Pin 5 of the UC2825 directly. The current feedback subcircuit, comprising two branch circuits, connects to Pin 5 of the UC2825. The first branch circuit of the current feedback subcircuit includes a zener diode D1. The anode of the zener diode D1 connects to the base of a triode Q2 through a filter circuit which is comprised of a resistance R6 and a capacitance C2. And the collector of the triode Q2 connects to Pin 5 of the UC2825 through resistance R5. The second branch circuit of the current feedback subcircuit includes a filter circuit, which includes resistances R1, R2, R3 and capacitance C1, C3, on one side, and the filter circuit of the second branch circuit connects to Pin 5 of the UC2825, on the other side. The filter circuit of the second branch circuit connects to the base of the triode Q1 through a zener diode D4. The collector of the triode Q1 connects to Pin S of the UC2825 through a resistance R4. RT subcircuit, voltage feedback subcircuit and current feedback subcircuit working together would change the RC constant of UC2825, thus changing the working frequency.

The output circuit includes two output subcircuits. One output subcircuit connects to Pin 11 of the UC2825 and the other connects to Pin 14. These two output subcircuits have similar circuit structure. The first output subcircuit connects to Pin 11 of the UC2825 through a resistance R17 while the second subcircuit connects to Pin 14 of the UC2825 through a resistance R16. The first output subcircuit is grounding through a resistance R19 for filtering clutter signal and through a diode D6 for protecting the UC2825. On the other side, the second output subcircuit is grounding through a resistance R18 for filtering clutter signal and through a diode D5 for protecting the UC2825.

The high speed controller 100 is encapsulated to form an independent component with a 8-pin connector for output. The pin assignment of the new design is: Pin 1 and Pin 3 for output; Pin 2 for common grounding; Pin 4 for input working power (Vcc) which is 12 Vdc(nom.); Pin 5 is used as shut down control; Pin 6 is voltage feedback input; Pin 7 for current feedback input; Pin 8 for oscillation frequency adjustment. All components of 100 are placed on a 1 mm FR4 PCB, size 46.0 mm×19.0 mm as in FIG. 11 and FIG. 12 and encapsulated in a metal casing (FIG. 13) with a 8-pin connector and fully potted.

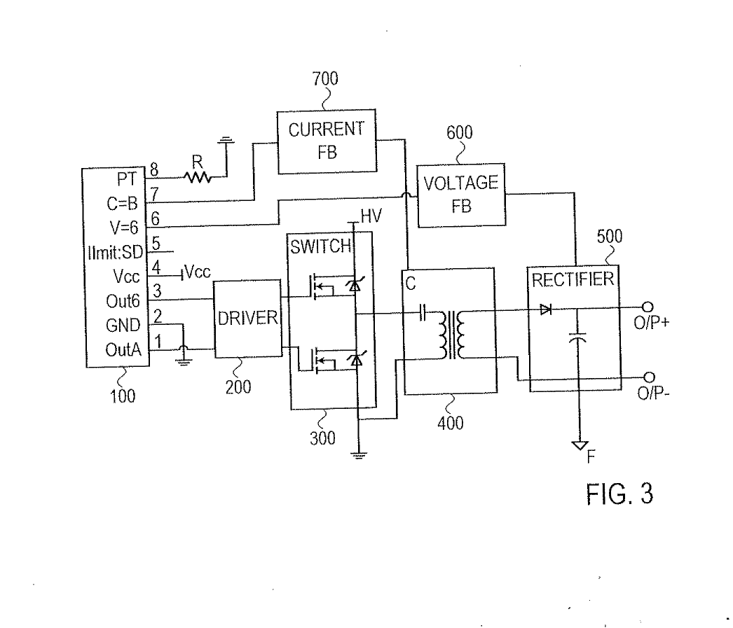

FIG. 3 is a block diagram illustrating a switching mode power supply incorporating with the new design (100) as a switching controller. Referring to FIG. 3, the high speed controller 100, is working as the kernel controller of the switching mode power supply, driving the switching mode power supply in PWM mode and in FM mode. Pin 1 and Pin 3 of the high speed controller 100 connect to a driver 200, and the outputs of the driver 200 connect to a switch 300 which is basically two MOSFETs in series. The output of the switch 300 is connected through a capacitor C to the primary winding of a transformer 400 whose leakage inductance is L. The secondary winding of the transformer 400 is then connected to a rectifier 500 with an electrolytic capacitor to acquire a DC output voltage.

The switching mode power supply includes a voltage feedback circuit(VFB) 600 and a current feedback circuit(CFB) 700. The voltage feedback circuit 600, sense the output voltage and send the feedback signal to Pin 6 of the high speed controller 100. The current feedback circuit 700, sense the feedback signal from transformer 400 and input through Pin 7 to the high speed controller 100.

Control signal to the switch 300 is from driver 200, and the power input to the switch 300 (HV) may probably from a PFC unit which is not shown in the figure. The transformer unit 400 includes a toroid or E core, with primary winding and secondary winding whose leakage inductance L, and a capacitance C, which is connected to the primary winding. This is the LC resonant circuit which dominates the whole function of the switching mode power supply.

The rectifier 500 includes a diode and a capacitance.

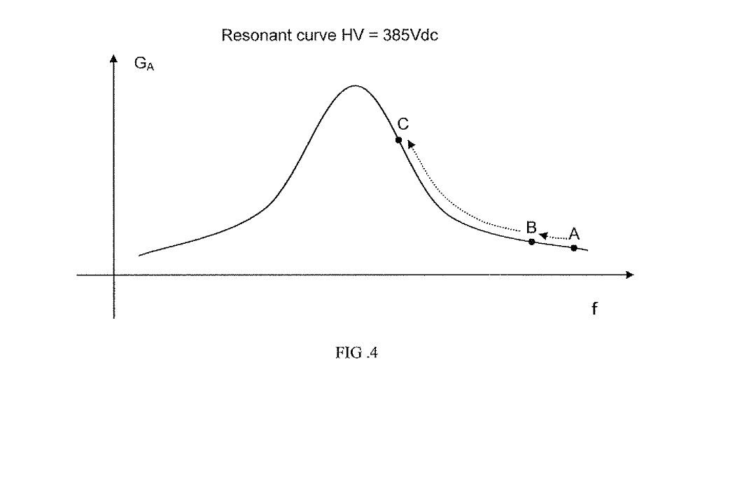

FIG. 4 is the resonant curve of the switching mode power supply in accordance with the preferred embodiment of the invention. Ideally, when 385V DC is introduced to the HV of the switch 300, RT, L and C in the circuit would be so chosen that when the power supply is in function and in open load, the working frequency would be high and probably at point A in FIG. 4. There is only weak current feedback signal, the FM enhancement network 110 will not be fully activated, and PWM control mode is predominating the process. As output load increased, the resonant point would shift towards B in FIG. 4, and it is still in PWM mode, and working frequency would be slightly changed only because the current feedback signal level is not high enough to fully activate the FM enhancement network 110.

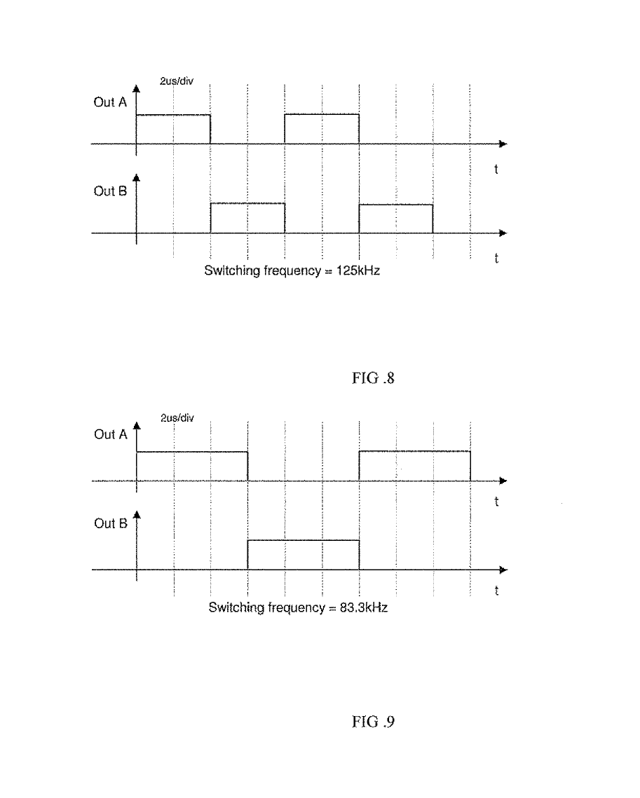

When working in PWM mode, FIG. 5˜FIG. 7 show PWM pulse control waveform at 5%, 10% and 20% load. These waveforms show that when output power is in light level (<30% load) the change in pulse width is outstanding while frequency change is not so significant PWM control mode is predominating the process, and the pulse width will be increased as the load is increasing.

When output load increase to a certain level (>30% of full load) and the CFB signal level rise to approximately 1˜4V DC, the FM enhancement network 110 is fully activated, and FM mode control now predominates the whole process. As output power increase from 30% to 100% full load, change of pulse width is not significant. The working frequency of the power supply may change from 200 kHz to 80 kHz indicating that the module is working on the resonant curve, probably shifting from point B to point C in FIG. 4.

FIG. 8 is PWM pulse control waveform at 50% load and FIG. 9 is PWM pulse control waveform at 100% load. The frequency of the high speed controller 100 in FIG. 8 and FIG. 9 are 125 kHz and 83.3 kHz. It shows that when the load increases, the frequency will decrease, and the power loss of most ferrite materials is smaller in 80 kHz than in 200 kHz.

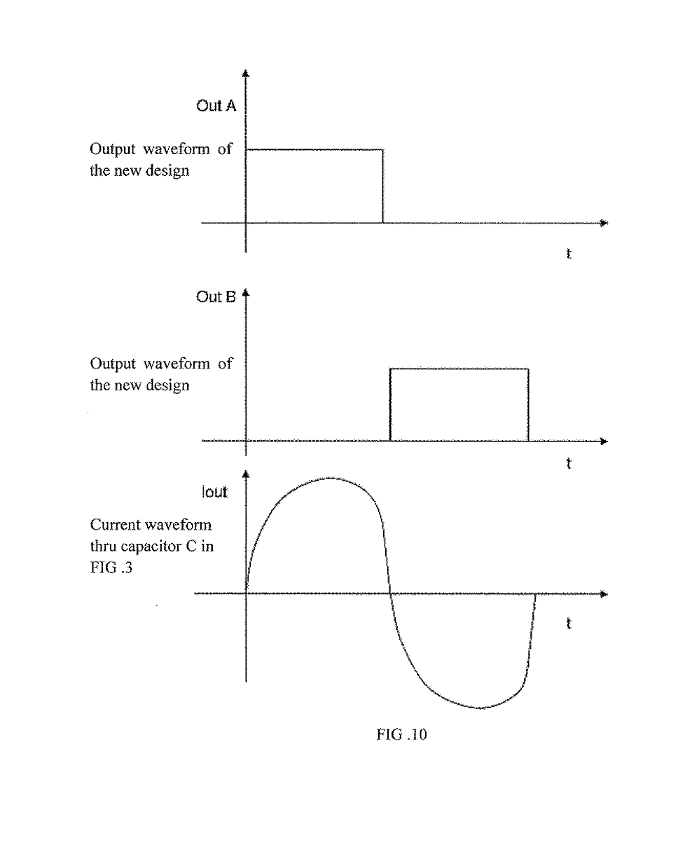

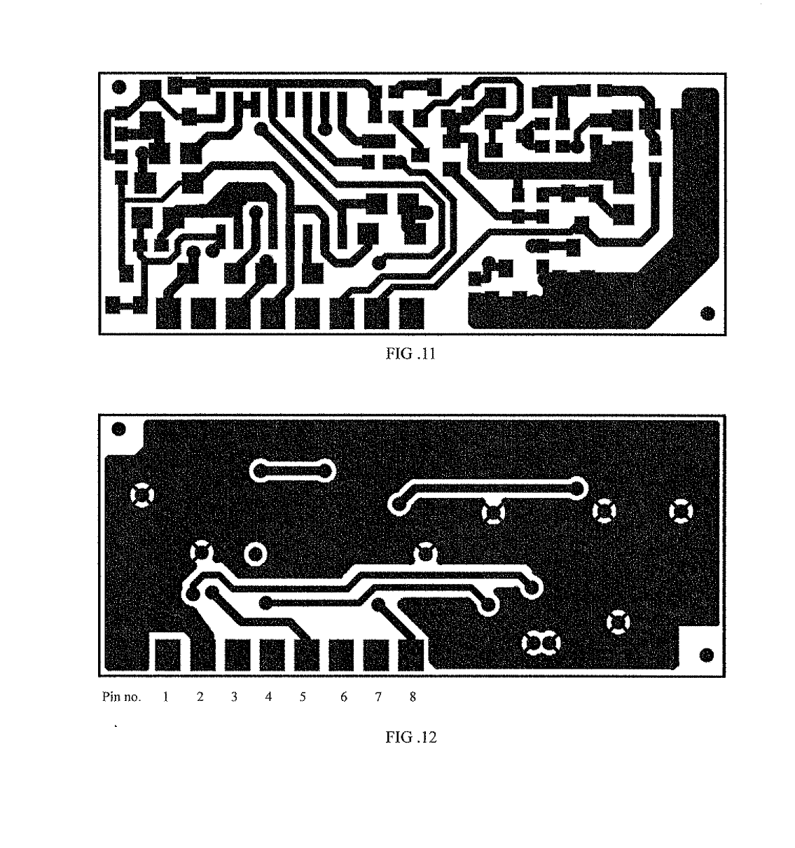

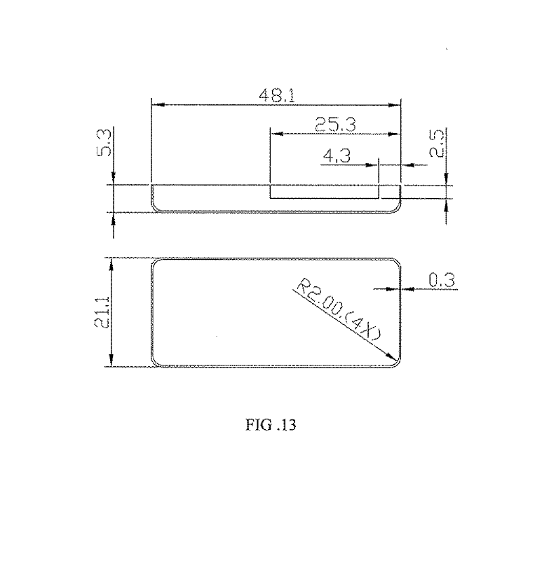

FIG. 10 is the output pulse of the new design and the output current waveform through LC circuit. When it is in FM mode control mode, the output current waveform tends to be a sinusoidal waveform, which indicates that switching loss is limited and high efficiency is promising.

As the output load of the power supply further increases and when the CFB feedback signal to Pin 7 raised to 5V DC or more, the FM enhancement network 110 stop functioning and the whole current control network comes to a halt and the high speed controller 100 would turn to hiccup mode. So the switching mode power supply will be protected.

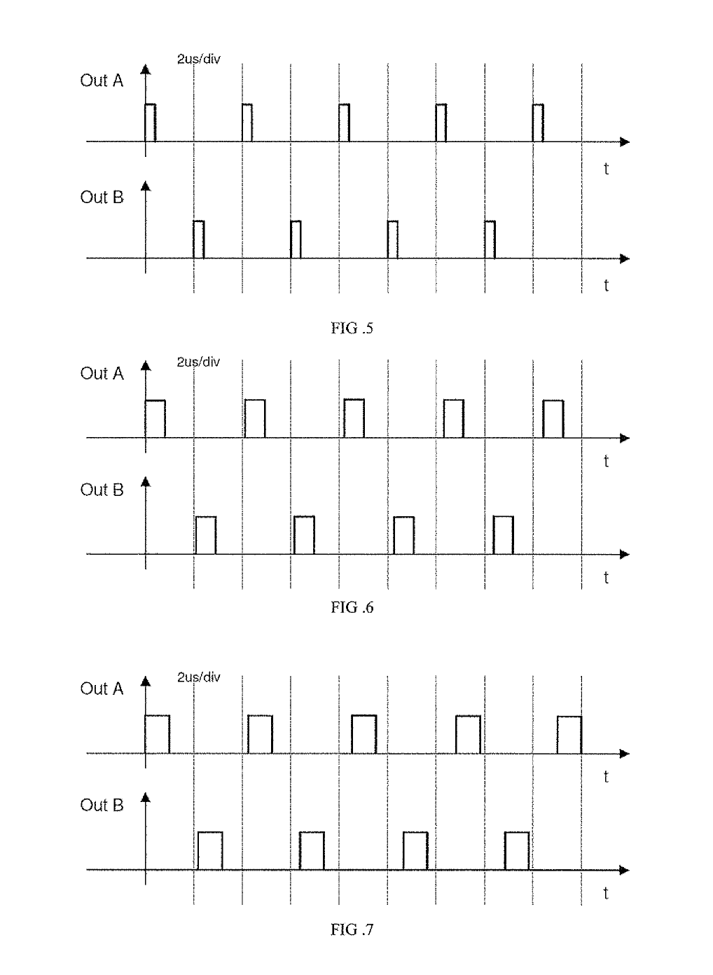

As shown in FIG. 6 to FIG. 10, the high speed controller 100 is working simultaneously both in FM and PWM mode. This switching mode power supply can automatically switch the working mode according to the load condition. When power supply output power is low, it would shift to PWM predominating mode operation (FM can be neglected) where PWM IC is excellent for this purpose, and when the output load increases and may eventually up to its maximum value, the controller turns to FM mode control predominate where the efficiency is high and resonant frequency shifted to the lower side.

The foregoing description is just a basic explanation of the invention. It is not intended to exhaustive or to limit the invention. Any modifications, variations, and amelioration without departing from the spirit and scope of the present invention should be included in the scope of the prevent invention.

1. A high speed controller, wherein, including:
PWM control chip (120): providing high speed controller PWM function;
output circuit (130): sending out PWM working signal and frequency modulation working signal;
FM enhancement network (110): effectively vary the oscillation frequency and pulse width of the PWM control chip (120), and according to the feedback for different load conditions;
output circuit (130), FM enhancement network (110) and IC (120) are all assembled in a PCB, and encapsulated in a metal case, with a 8-pin connector, and fully potted with epoxy.

2. The high speed controller according to claim 1, wherein, the PWM control chip (120) is PWM control IC UC2825.

3. The high speed controller according to claim 2, wherein, the FM enhancement network (110) includes RT subcircuit, voltage feedback subcircuit and current feedback subcircuit; RT subcircuit connects to Pin 5 of the UC2825; current feedback subcircuit connects to Pin 5 of the UC2825; voltage feedback subcircuit connects to Pin 1 of the UC2825.

4. The high speed controller according to claim 2, wherein, output circuit (130) includes two output subcircuits, one connects to Pin 11 of the UC2825, and the other connects to Pin 14 of the UC2825.

5. A switching mode power supply, wherein, including:
a high speed controller(100);
a driver (200) connected to the output circuit (130) of the high speed controller (100);
a switch (300) connected to the driver (200);
a transformer (400) with leakage inductance (L) and a capacitor (C) connected to the switch (300);
a rectifier (500) connected to the secondary winding of transformer (400);
current feedback circuit (700), connected to the transformer (400) and the high speed controller (100);
voltage feedback circuit (600), connected to the rectifier (500) and the high speed controller (100).

6. The switching mode power supply according to claim 5, wherein, the switch (300) includes two switching modules.

7. The switching mode power supply according to claim 6, wherein, the leakage inductance (L) of the transformer (400) and capacitor (C) together build up the resonant circuit.
